(19) United States
(12) Patent Application Publication
(10) Pub. No.: US 2021/0020697 A1
(43) Pub. Date: Jan. 21, 2021

(54) ORGANIC OPTOELECTRONIC DEVICE

(71) Applicant: The Regents of the University of Michigan, Ann Arbor, MI (US)

(72) Inventors: Stephen R. Forrest, Ann Arbor, MI (US); Xiaozhou Che, Sunnyvale, CA (US); Yongxi Li, Ann Arbor, MI (US)

(21) Appl. No.: 16/931,960

(22) Filed: Jul. 17, 2020

Related U.S. Application Data
(60) Provisional application No. 62/876,050, filed on Jul. 19, 2019.

(51) Int. Cl. H01L 27/30; H01L 51/44

(52) U.S. Cl. CPC H01L 27/302; H01L 51/441

(57) ABSTRACT

An organic optoelectronic device comprises a first electrode, a first infrared photovoltaic subcell positioned over the first electrode, a second infrared photovoltaic subcell positioned over the first near-infrared subcell, and a first visible photovoltaic subcell positioned over the second near-infrared subcell, a second electrode positioned between the second near-infrared photovoltaic subcell and the first visible photovoltaic subcell, and a third electrode positioned over the first visible photovoltaic subcell, wherein the first electrode and the third electrode are held at the same potential relative to the second electrode.

### CROSS-REFERENCE TO RELATED APPLICATIONS

This application claims priority to U.S. Provisional Application No. 62/876,050, filed on Jul. 19, 2019, incorporated herein by reference in its entirety.

### STATEMENT REGARDING FEDERALLY SPONSORED RESEARCH OR DEVELOPMENT

This invention was made with government support under DE-EE0006708 awarded by the U.S. Dept. of Energy. The government has certain rights in the invention.

### BACKGROUND

Optoelectronic devices rely on the optical and electronic properties of materials to either produce or detect electromagnetic radiation electronically or to generate electricity from ambient electromagnetic radiation.

Photosensitive optoelectronic devices convert electromagnetic radiation into electricity. Solar cells, also called photovoltaic (PV) devices or cells, are a type of photosensitive optoelectronic device that is specifically used to generate electrical power. PV devices, which may generate electrical energy from light sources other than sunlight, may be used to drive power consuming loads to provide, for example, lighting, heating, or to power electronic circuitry or devices such as calculators, radios, computers or remote monitoring or communications equipment. These power generation applications may involve the charging of batteries or other energy storage devices so that operation may continue when direct illumination from the sun or other light sources is not available, or to balance the power output of the PV device with the specific applications requirements.

Traditionally, photosensitive optoelectronic devices have been constructed of a number of inorganic semiconductors, e.g., crystalline, polycrystalline and amorphous silicon, gallium arsenide, cadmium telluride, and others.

More recent efforts have focused on the use of organic photovoltaic (OPV) cells to achieve acceptable photovoltaic conversion efficiencies with economical production costs. OPVs offer a low-cost, light-weight, and mechanically flexible route to solar energy conversion. Compared with polymers, small molecule OPVs share the advantage of using materials with well-defined molecular structures and weights. This leads to a reliable pathway for purification and the ability to deposit multiple layers using highly controlled thermal deposition without concern for dissolving, and thus damaging, previously deposited layers or sub-cells.

In contrast with the inorganic materials, organic molecules usually exhibit narrow absorption bands, making such materials favorable for semitransparent applications. Very recently, non-fullerene (NF) acceptors were developed for high efficiency OPVs. In contrast with fullerene, which contributes to EQE only at wavelengths less than 700 nm, energy levels of NF acceptors can be tuned to absorb at different spectral regions. When pairing a near-infrared (NIR)-absorbing NF acceptor with an NIR donor, an OPV cell can be fabricated having high transparency in the visible spectrum while showing high EQE in the NIR region. Combining green-absorbing donors and acceptors will lead to higher open circuit voltage (Voc) while having a narrower absorption spectrum in the visible range compared to fullerene-based cells.

As used herein, the term “organic” includes polymeric materials as well as small molecule organic materials that may be used to fabricate organic opto-electronic devices. “Small molecule” refers to any organic material that is not a polymer, and “small molecules” may actually be quite large. Small molecules may include repeat units in some circumstances. For example, using a long chain alkyl group as a substituent does not remove a molecule from the “small molecule” class. Small molecules may also be incorporated into polymers, for example as a pendent group on a polymer backbone or as a part of the backbone. Small molecules may also serve as the core moiety of a dendrimer, which consists of a series of chemical shells built on the core moiety. The core moiety of a dendrimer may be a fluorescent or phosphorescent small molecule emitter. A dendrimer may be a “small molecule,” and it is believed that all dendrimers currently used in the field of organic optoelectronics are small molecules.

As used herein, “top” means furthest away from the substrate, while “bottom” means closest to the substrate. Where a first layer is described as “disposed over” a second layer, the first layer is disposed further away from substrate. There may be other layers between the first and second layer, unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

A ligand may be referred to as “photoactive” when it is believed that the ligand directly contributes to the photoactive properties of an optoelectronic material. A ligand may be referred to as “ancillary” when it is believed that the ligand does not contribute to the photoactive properties of an optoelectronic material, although an ancillary ligand may alter the properties of a photoactive ligand.

As used herein, and as would be generally understood by one skilled in the art, a first “Highest Occupied Molecular Orbital” (HOMO) or “Lowest Unoccupied Molecular Orbital” (LUMO) energy level is “greater than” or “higher than” a second HOMO or LUMO energy level if the first energy level is closer to the vacuum energy level. Since ionization potentials (IP) are measured as a negative energy relative to a vacuum level, a higher HOMO energy level corresponds to an IP having a smaller absolute value (an IP that is less negative). Similarly, a higher LUMO energy level corresponds to an electron affinity (EA) having a smaller absolute value (an EA that is less negative). On a conventional energy level diagram, with the vacuum level at the top, the LUMO energy level of a material is higher than the HOMO energy level of the same material. A “higher” HOMO or LUMO energy level appears closer to the top of such a diagram than a “lower” HOMO or LUMO energy level.

As used herein, and as would be generally understood by one skilled in the art, a first work function is “greater than” or “higher than” a second work function if the first work function has a higher absolute value. Because work functions are generally measured as negative numbers relative to vacuum level, this means that a “higher” work function is more negative. On a conventional energy level diagram, with the vacuum level at the top, a “higher” work function is illustrated as further away from the vacuum level in the downward direction. Thus, the definitions of HOMO and LUMO energy levels follow a different convention than work functions.

### SUMMARY OF THE DISCLOSURE

In one aspect, an organic optoelectronic device comprises a first electrode, a first infrared photovoltaic subcell positioned over the first electrode, a second infrared photovoltaic subcell positioned over the first near-infrared subcell, and a first visible photovoltaic subcell positioned over the second near-infrared subcell, a second electrode positioned between the second near-infrared photovoltaic subcell and the first visible photovoltaic subcell, and a third electrode positioned over the first visible photovoltaic subcell, wherein the first electrode and the third electrode are held at the same potential relative to the second electrode.

In one embodiment, the first electrode and the third electrode are electrically connected. In one embodiment, the first and second infrared photovoltaic subcells are near-infrared photovoltaic subcells having a response spectrum comprising a wavelength range of 640 nm to 1100 nm. In one embodiment, the first infrared photovoltaic subcell has a response spectrum comprising a wavelength range of 800 nm to 1100 nm, and the second infrared photovoltaic subcell has a response spectrum comprising a wavelength range of 640 nm to 1100 nm. In one embodiment, the first infrared photovoltaic subcell comprises a non-fullerene acceptor. In one embodiment, the first visible photovoltaic subcell has a transparency from 30% to 80%. In one embodiment, the first visible photovoltaic subcell has a transparency of about 50%. In one embodiment, the sum of a Voc of the first infrared photovoltaic subcell and a Voc of the second infrared photovoltaic subcell is about equal to a Voc of the first visible photovoltaic subcell.

In one embodiment, each of the first and second infrared photovoltaic subcells has a balanced photocurrent of at least 10 mA/cm². In one embodiment, each of the first and second infrared photovoltaic subcells has a balanced photocurrent of at least 12 mA/cm². In one embodiment, the device further comprises a third infrared photovoltaic subcell positioned between the second infrared photovoltaic subcell and the second electrode.

In one aspect, an organic optoelectronic device comprises a first electrode, a first infrared photovoltaic subcell positioned over the first electrode, a second infrared photovoltaic subcell positioned over the first near-infrared subcell, and a first visible photovoltaic subcell positioned over the second near-infrared subcell, and a second electrode positioned over the first visible photovoltaic subcell, wherein the first electrode and the third electrode are held at the same potential relative to the second electrode.

In one embodiment, the device further comprises a third electrode positioned between the second infrared photovoltaic subcell and the first visible photovoltaic subcell. In one embodiment, the first infrared photovoltaic subcell has a response spectrum comprising a wavelength range of 800 nm to 1100 nm, and the second infrared photovoltaic subcell has a response spectrum comprising a wavelength range of 640 nm to 840 nm.

In one embodiment, the first visible photovoltaic subcell has a response spectrum comprising a wavelength range of 350 nm to 640 nm. In one embodiment, the first infrared photovoltaic subcell comprises a non-fullerene acceptor. In one embodiment, the first visible photovoltaic subcell has a transparency from 30% to 80%. In one embodiment, the energy loss of each subcell is in a range from 0.3 to 0.7 eV. In one embodiment, a Voc from the first electrode to the second electrode is at least 2.4 V. In one embodiment, the Voc from the first electrode to the second electrode is at least 3 V.

### BRIEF DESCRIPTION OF THE DRAWINGS

The foregoing purposes and features, as well as other purposes and features, will become apparent with reference to the description and accompanying figures below, which are included to provide an understanding of the disclosure and constitute a part of the specification, in which like numerals represent like elements, and in which:

FIG. 1 shows an exemplary OPV device;

FIG. 2 shows an exemplary multijunction OPV device;

FIG. 3 shows a graph of an exemplary EQE spectrum;

FIG. 4A shows a graph of efficiency as a function of transparency;

FIG. 4B shows a graph of the product of efficiency and transparency as a function of transparency;

FIG. 5 shows an exemplary multijunction OPV device;

FIG. 6A shows a graph of an exemplary EQE spectrum;

FIG. 6B shows a graph of efficiency as a function of transparency; and

FIG. 6C shows a graph of the product of efficiency and transparency as a function of transparency.

### DETAILED DESCRIPTION

It is to be understood that the figures and descriptions of the present disclosure have been simplified to illustrate elements that are relevant for a clear understanding of the present disclosure, while eliminating, for the purpose of clarity, many other elements found in related systems and methods. Those of ordinary skill in the art may recognize that other elements and/or steps are desirable and/or required in implementing the present disclosure. However, because such elements and steps are well known in the art, and because they do not facilitate a better understanding of the present disclosure, a discussion of such elements and steps is not provided herein. The disclosure herein is directed to all such variations and modifications to such elements and methods known to those skilled in the art.

Unless defined otherwise, all technical and scientific terms used herein have the same meaning as commonly understood by one of ordinary skill in the art to which this disclosure belongs. Although any methods and materials similar or equivalent to those described herein can be used in the practice or testing of the present disclosure, exemplary methods and materials are described.

As used herein, each of the following terms has the meaning associated with it in this section.

The articles “a” and “an” are used herein to refer to one or to more than one (i.e., to at least one) of the grammatical object of the article. By way of example, “an element” means one element or more than one element.

“About” as used herein when referring to a measurable value such as an amount, a temporal duration, and the like, is meant to encompass variations of ±20%, ±10%, ±5%, ±1%, and ±0.1% from the specified value, as such variations are appropriate.

Throughout this disclosure, various aspects of the disclosure can be presented in a range format. It should be understood that the description in range format is merely for convenience and brevity and should not be construed as an inflexible limitation on the scope of the disclosure. Accordingly, the description of a range should be considered to have specifically disclosed all the possible subranges as well as individual numerical values within that range. For example, description of a range such as from 1 to 6 should be considered to have specifically disclosed subranges such as from 1 to 3, from 1 to 4, from 1 to 5, from 2 to 4, from 2 to 6, from 3 to 6 etc., as well as individual numbers within that range, for example, 1, 2, 2.7, 3, 4, 5, 5.3, 6 and any whole and partial increments therebetween. This applies regardless of the breadth of the range.

As used herein, the terms “electrode” and “contact” may refer to a layer that provides a medium for delivering current to an external circuit or providing a bias current or voltage to the device. For example, an electrode, or contact, may provide the interface between the active regions of an organic photosensitive optoelectronic device and a wire, lead, trace or other means for transporting the charge carriers to or from the external circuit. Examples of electrodes include anodes and cathodes, which may be used in a photosensitive optoelectronic device.

As used herein, the term “transparent” may refer to a material that permits at least 50% of the incident electromagnetic radiation in relevant wavelengths to be transmitted through it. In a photosensitive optoelectronic device, it may be desirable to allow the maximum amount of ambient electromagnetic radiation from the device exterior to be admitted to the photoconductive active interior region. That is, the electromagnetic radiation must reach a photoconductive layer(s), where it can be converted to electricity by photoconductive absorption. This often dictates that at least one of the electrical contacts or electrodes should be minimally absorbing and minimally reflecting of the incident electromagnetic radiation. In some cases, such a contact should be transparent or at least semi-transparent. In one embodiment, the transparent material may form at least part of an electrical contact or electrode.

As used herein, the term “semi-transparent” may refer to a material that permits some, but less than 50% transmission of ambient electromagnetic radiation in relevant wavelengths. Where a transparent or semi-transparent electrode is used, the opposing electrode may be a reflective material so that light which has passed through the cell without being absorbed is reflected back through the cell.

As used and depicted herein, a “layer” refers to a member or component of a device, for example an optoelectronic device, being principally defined by a thickness, for example in relation to other neighboring layers, and extending outward in length and width. It should be understood that the term “layer” is not necessarily limited to single layers or sheets of materials. In addition, it should be understood that the surfaces of certain layers, including the interface(s) of such layers with other material(s) or layers(s), may be imperfect, wherein said surfaces represent an interpenetrating, entangled or convoluted network with other material(s) or layer(s). Similarly, it should also be understood that a layer may be discontinuous, such that the continuity of said layer along the length and width may be disturbed or otherwise interrupted by other layer(s) or material(s).

As used herein, a “photoactive region” refers to a region of a device that absorbs electromagnetic radiation to generate excitons. Similarly, a layer is “photoactive” if it absorbs electromagnetic radiation to generate excitons. The excitons may dissociate into an electron and a hole in order to generate an electrical current.

As used herein, the terms “infrared cell,” “infrared layer,” “infrared subcell,” or “infrared photovoltaic subcell” refers to a photoactive region which generates excitons in response to electromagnetic radiation in at least a portion of the infrared spectrum. The term “near infrared,” or NIR, refers to a portion or all of the subset of the infrared spectrum near to the visible spectrum, which in some embodiments refers to wavelengths in the range of 750 nm to 1.4 μm.

An “NIR subcell” therefore refers to a photoactive region which generates excitons in response to electromagnetic radiation in at least a portion of the NIR spectrum. The terms “visible subcell,” “visible cell,” or “visible photovoltaic subcell” refer to a photoactive region which generates excitons in response to electromagnetic radiation in at least a portion of the visible spectrum, which in some embodiments refers to wavelengths in the range of 380 nm to 749 nm.

As used herein, the terms “donor” and “acceptor” refer to the relative positions of the highest occupied molecular orbital (“HOMO”) and lowest unoccupied molecular orbital (“LUMO”) energy levels of two contacting but different organic materials. If the LUMO energy level of one material in contact with another is lower, then that material is an acceptor. Otherwise it is a donor. It is energetically favorable, in the absence of an external bias, for electrons at a donor-acceptor junction to move into the acceptor material, and for holes to move into the donor material.

As used herein, a first “Highest Occupied Molecular Orbital” (HOMO) or “Lowest Unoccupied Molecular Orbital” (LUMO) energy level is “greater than” or “higher than” a second HOMO or LUMO energy level if the first energy level is closer to the vacuum energy level. Because ionization potentials (IP) are measured as a negative energy relative to a vacuum level, a higher HOMO energy level corresponds to an IP having a smaller absolute value (an IP that is less negative). Similarly, a higher LUMO energy level corresponds to an electron affinity (EA) having a smaller absolute value (an EA that is less negative). On a conventional energy level diagram, with the vacuum level at the top, the LUMO energy level of a material is higher than the HOMO energy level of the same material. A “higher” HOMO or LUMO energy level appears closer to the top of such a diagram than a “lower” HOMO or LUMO energy level.

As used herein, the term “band gap” (E_{g}) of a polymer may refer to the energy difference between the HOMO and the LUMO. The band gap is typically reported in electron volts (eV). The band gap may be measured from the UV-vis spectroscopy or cyclic voltammetry. A “low band gap” polymer may refer to a polymer with a band gap below 2 eV, e.g., the polymer absorbs light with wavelengths longer than 620 nm.

As used herein, the term “excitation binding energy” (EB) may refer to the following formula: EB=(M⁺+M⁻)−(M*+M), where M⁺ and M⁻ are the total energy of a positively and negatively charged molecule, respectively; M* and M are the molecular energy at the first singlet state (Si) and ground state, respectively. Excitation binding energy of acceptor or donor molecules affects the energy offset needed for efficient exciton dissociation. In certain examples, the escape yield of a hole increases as the HOMO offset increases. A decrease of exciton binding energy EB for the acceptor molecule leads to an increase of hole escape yield for the same HOMO offset between donor and acceptor molecules.

As used herein, “power conversion efficiency” (PCE) (η_{ρ}) may be expressed as:

$${η}_{ρ} = \frac{{V}_{OC} * F F * {J}_{SC}}{{P}_{O}}$$

wherein V_{OC} is the open circuit voltage, FF is the fill factor, J_{SC} is the short circuit current, and P_{O} is the input optical power.

As disclosed herein, the various compositions or molecules may be provided within a solar cell or organic photovoltaic (OPV) cell. As contemplated herein, the various compositions or molecules for an OPV cell disclosed herein may be advantageous in providing one or more improvements over conventionally known OPV cells. Specifically, the various OPV cell layers and devices may provide an improved power conversion efficiency over conventionally known OPV cells and devices.

Although certain embodiments of the disclosure are discussed in relation to one particular device or type of device (for example OPVs) it is understood that the disclosed improvements to light outcoupling properties of a substrate may be equally applied to other devices, including but not limited to OLEDs, PLEDs, charge-coupled devices (CCDs), photosensors, or the like. Organic Photovoltaic Cells

As disclosed herein, various compositions or molecules may be provided within a solar cell or organic photovoltaic (OPV) cell. As supported by the Example section below, the various compositions or molecules for a semi-transparent OPV (ST-OPV) cell disclosed herein may be advantageous in providing one or more improvements over conventionally known ST-OPV cells. Such ST-OPVs may be integrated within a window pane to improve energy harvesting of solar irradiation. Reducing visible reflection and absorption are important to maximizing transmission and light utilization efficiency (LUE), which is the product of the power conversion efficiency and the average photonic transparency.

For example, the various OPV cell layers and devices disclosed herein may provide semi-transparent OPV cells (ST-OPVs) and devices having improved visible transmission and LUE over conventionally known ST-OPVs. Moreover, neutral and multi-colored ST-OPVs incorporating multilayer coatings may provide a wide variety of transmission colors (e.g., blue, green and red) with high efficiencies.

As disclosed herein, the improved semi-transparent OPV cells (ST-OPVs) and devices may include: an optical outcoupling (OC) layer, a first electrode, an active region or layer, a second electrode, and an anti-reflection coating (ARC) layer. Additional or fewer layers may be included as well.

The presence of the OC and/or ARC layer may enhance visible transmission within the ST-OPV cell while reflecting the near-infrared (NIR) light back into the cell. This may improve (e.g., double) the light utilization efficiency (LUE) when compared with a reference cell lacking the OC and ARC layers. In certain examples disclosed herein, the maximum LUE is at least 2.5%, at least 3%, at least 3.25%, at least 3.5%, at least 3.55%, or about 3.56% for an efficiency of at least 5.0%, at least 6.0%, at least 7.0%, or at least 8.0% at 1 sun, AM1.5 G simulated emission is achievable.

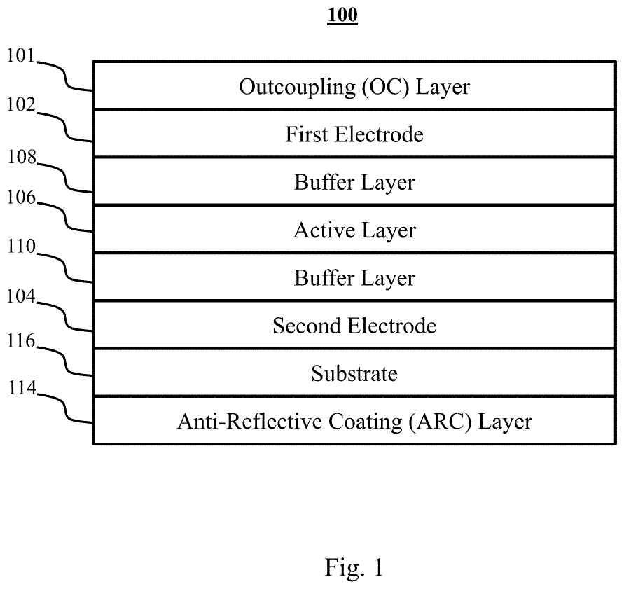

The various layers and their properties are disclosed in greater detail below with reference to FIG. 1.

### Organic Photovoltaic Cell Overview

FIG. 1 depicts an example of various layers of an OPV device. The OPV device may include an OPV cell 100 having a first electrode 102 and a second electrode 104 (e.g., an anode and a cathode) in superposed relation. The OPV cell may also include an active layer 106 positioned between the two electrodes 102, 104. In certain examples, at least one buffer layer 108 may be positioned between the first electrode 102 and the active layer 106. Additionally, or alternatively, at least one buffer layer 110 may be positioned between the active layer 106 and the second electrode 104.

In certain examples, an OC layer may be positioned adjacent to the first or second electrode 102, 104, such that the electrode is positioned between the OC layer and the active layer. In the depicted device 100, the OC layer 112 is positioned adjacent to the first electrode 102. An ARC layer may be positioned adjacent to the first or second electrode 102, 104, or adjacent to a substrate layer such that the electrode is positioned between the OC layer and the active layer. In the depicted device 100, the ARC layer is positioned adjacent to substrate 116, which itself is adjacent to second electrode 104. In some examples, both an OC layer and an ARC layer are present, wherein one of the OC layer or the ARC layer is positioned adjacent to the first electrode, and the other layer is positioned adjacent to the second electrode.

In certain examples, additional internal layers may be present within the OPV cell, such as an interfacial layer.

Non-limiting examples of the various compositions of the various layers of the OPVs are described herein.

### Electrodes

The first and second electrodes 102, 104 may be any transparent or semi-transparent material, such as graphene, carbon nanotubes, conductive polymers, metallic nanostructures, or ultrathin metal compositions. In certain embodiments, ultrathin metal films provide unique advantages of high conductivity, mechanical flexibility and simple preparation. The thickness of each electrode may be less than 100 nm, less than 50 nm, less than 10 nm, in a range of 0.1-1000 nm, 1-10 nm, 0.1-10 nm, 5-10 nm, 5-50 nm, 10-100 nm, or 50-500 nm, 100-1000 nm.

In certain examples, the first electrode 102 may be the anode and the second electrode 104 may be the cathode. While some examples disclosed herein refer to the first electrode 102 as the anode, the alternative may apply, wherein the first electrode is the cathode.

In some examples, the first electrode 102 and/or the second electrode 104 may include a conductive metal oxide, in some embodiments a transparent or semi-transparent conductive metal oxide, such as indium tin oxide (ITO), tin oxide (TiO), gallium indium tin oxide (GaITO), zinc oxide (ZnO), or zinc indium tin oxide (ZnITO). In other examples, the first electrode 102 and/or the second electrode 104 may include a thin metal layer, wherein the metal is selected from the group consisting of Ag, Au, Pd, Pt, Ti, V, Zn, Sn, Al, Co, Ni, Cu, Cr, or combinations thereof. In yet other examples, the first electrode 102 and/or the second electrode 104 may include a conductive polymer, in some embodiments a transparent or semi-transparent conductive polymer, such as polyanaline (PANT), or 3,4-polyethyl-enedioxythiophene:polystyrenesulfonate (PEDOT:PSS).

### Active Layers

As noted above, at least one active region or layer 106 is present between the two electrodes 102, 104. The thickness of the active layer 106 is variable. In certain examples, the thickness of the active layer 106 may be between 0.1 nm and 1 μm, or between 0.1 nm and 500 nm, or between 1 nm and 200 nm, or between 1 nm and 100 nm, or less than 100 nm, or in a range of 10-100 nm, 50-100 nm, or 60-90 nm. In some embodiments the thickness of the active layer 106 is about 85 nm. In some embodiments, the active layer or region may comprise a plurality of subcells.

The active region or layer 106 positioned between the electrodes includes one or more compositions or molecules having an acceptor and a donor. In certain examples, the composition may be arranged as an acceptor-donor-acceptor (A-D-A′) or donor-acceptor-acceptor (d-a-a′). In other embodiments, more or fewer donors or more or fewer acceptors may be used.

Disclosed herein are various multi junction OPV devices including a plurality of subcells which may be connected in series, parallel, or a combination of both. The disclosed OPV devices in some embodiments may be configured to have a transparency of at least 40%, at least 50%, at least 60%, at least 70%, at least 80%, at least 90%, or at least 95%. In some embodiments, OPV devices may be transparent or semi-transparent across the entire visible spectrum or a portion of the visible spectrum.

Disclosed devices may have a multijunction PCE of at least 10%, at least 15%, at least 18%, at least 20%, at least 25%, at least 30%, at least 40%, or at least 50%.

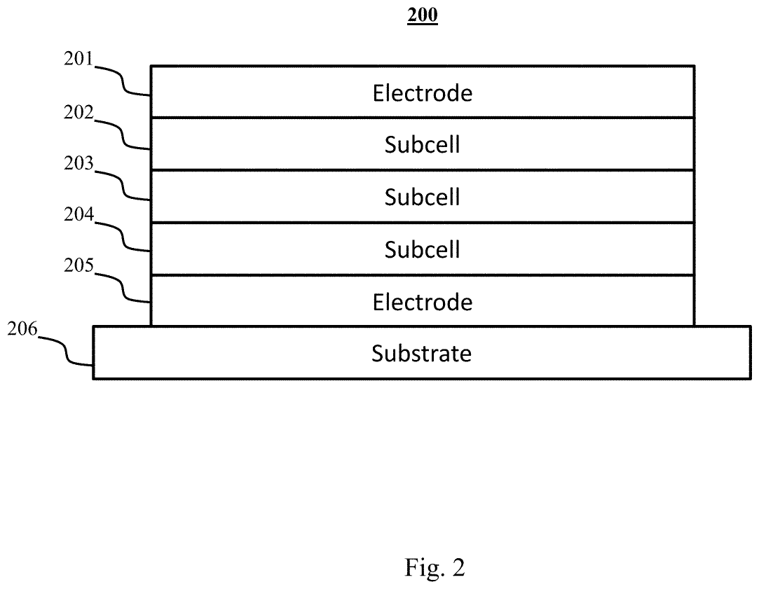

One exemplary device is shown with reference to FIG. 2. As shown in FIG. 2, an OPV may include first and second electrodes 201 and 205, with a plurality of subcells (202, 203, and 204) positioned in between. A device may further include a substrate 206 on which one electrode is deposited. Electrode 201 may in some embodiments be a cathode, for example a transparent cathode comprising ITO or some other transparent conductive material. Electrode 205 may in some embodiments be an anode, and may be transparent or opaque.

In the depicted embodiment of FIG. 2, the three subcells 202, 203, and 204 are arranged optically and electrically in series. Each subcell has an open circuit voltage (OCV) defined as the potential difference between one surface of the subcell and the other under open circuit conditions. The combined open circuit voltage of the three subcells is therefore equal to the sum of the open circuit voltages of the three subcells.

In one embodiment, subcell 202 is a visible light subcell, subcell 203 is a NIR subcell, and subcell 204 is an IR or FIR subcell. In one embodiment, subcells 202, 203, and 204 are arranged such that each subsequent subcell is sensitive to light in an equal or longer wavelength than the previous subcell.

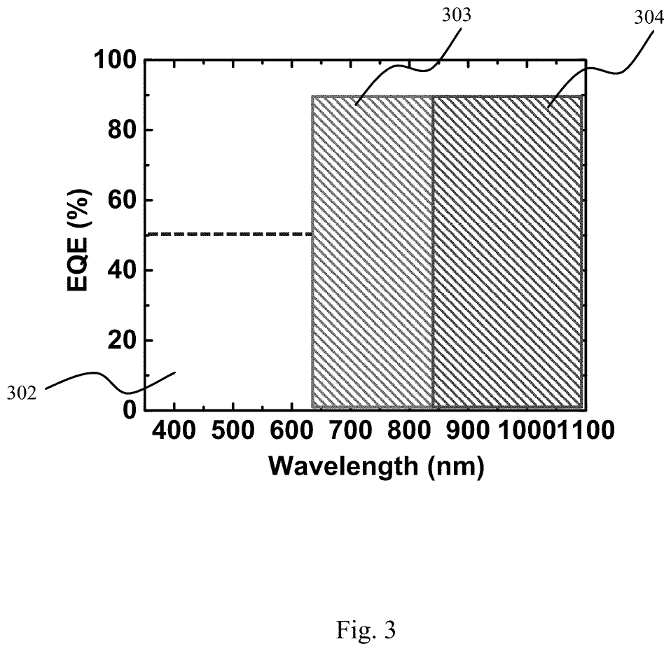

An exemplary EQE spectrum of triple junction comprising the three subcells in device 200 is shown in FIG. 3. In the depicted graph, it is assumed that the subcell EQE is 90% at wavelengths above 640 nm, and 100% minus the transparency percentage at wavelengths below 640 nm. Region 302 in FIG. 3 corresponds to subcell 202, and regions 303 and 304 correspond to subcells 203 and 204, respectively. In one embodiment, subcell 202 absorbs light with wavelengths in the range between 350 nm and 640 nm, with certain transparency from 30% to 80%. Subcell 202 may in some embodiments be current limiting, and in one embodiment the three subcells are connected in series without absorption overlap. It is assumed that subcell 203 absorbs light with wavelengths in the range between 640 nm and 840 nm, and subcell 204 absorbs light with wavelengths in the range between 840 nm and 1100 nm. In one embodiment, the fill factor of the triple junction (FFₜᵣᵢₚₗₑ) is between 0.2 and 1.0, between 0.5 and 1.0, between 0.6 and 0.9, between 0.7 and 0.8, or about 0.75.

In one embodiment, the energy loss (Ezoss) of each subcell is between 0.3 and 0.7 eV. In one embodiment, where the Voc of the triple junction is 1.9+1.5+1.1−3*Eₗₒₛₛ. In one embodiment, the balanced short circuit current (J_{SC}) between the NIR (203) and IR (204) subcells is about 12 mA/cm². In one embodiment, the J_{SC} of the triple-junction: J_{JC-visible}+0.1*(J_{SC-IR}-J_{SC-visible}).

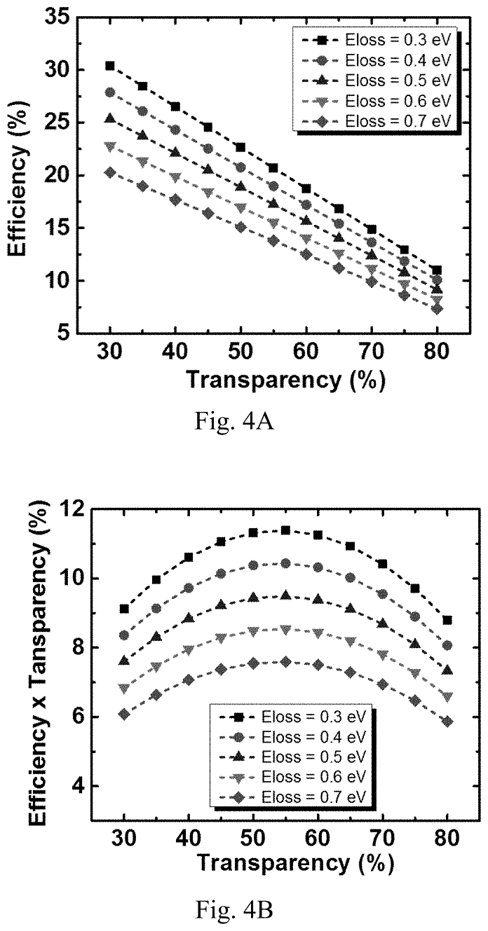

A graph of the efficiency calculated with each energy loss (boss) and visible subcell transparency is shown in FIG. 4A. With reference to FIG. 4A, efficiency increases with lower transparency and lower Eₗₒₛₛ, which determines the J_{SC} and V_{OC} respectively. As shown in FIG. 4A, a triple junction cell with 50% transparency in the visible range and single junction energy loss of 0.5 eV has an efficiency of 18.9%. FIG. 4B plots the product of calculated efficiency and device transparency. Higher transmission in the visible cell results in a larger current difference compared to the red subcells, which leads to a trade-off between transparency and efficiency. The peak value is around 55% transparency for all energy loss cases.

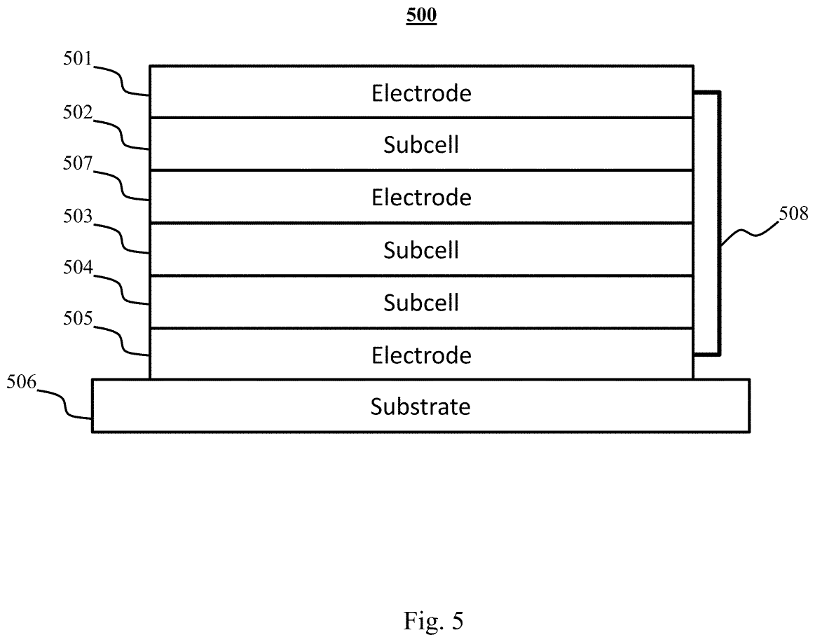

A second exemplary device 500 is shown in FIG. 5. Device 500 is positioned on optional substrate 506 and is similar in structure to device 200, except that device 500 includes a third electrode 507 positioned between subcell 502 and 503. Electrodes 501 and 505 may be held at the same potential relative to one another, for example by being electrically connected, for example via electrical connection 508. In the depicted arrangement, as would be understood by one skilled in the art, subcells 503 and 504 are arranged in series, with the series combination arranged in parallel with subcell 502. In such an exemplary configuration, electrodes 501 and 505 may be configured together as a cathode, while electrode 507 may be configured as an anode. In such a configuration, some or all of electrodes 501, 507, and 505 may be at least semi-transparent. In one embodiment, electrodes 501 and 507 are transparent.

In one embodiment, subcells 503 and 504 are identical subcells, while in another embodiment subcells 503 and 504 are different from one another, but configured such that their combined V_{OC} is approximately equal to the V_{OC} of subcell 502.

In one embodiment, subcells 503 and 504 are NIR subcells arranged in series, and subcell 502 is a visible subcell, for example with absorption between 350 nm and 640 nm. In one embodiment, the EQE of the subcells is 90% above 640 nm and 100% minus the transparency percentage at wavelengths below 640 nm. In one embodiment, the V_{OC} of subcell 502 is equal to about twice the V_{OC} of each of subcells 503 and 504, which means the V_{OC} of the triple junction is about the V_{OC} of subcell 502. In one embodiment, the V_{OC} of subcell 502 is about 1.9V and the V_{OC} of each of subcells 503 and 504 is about 1.1V, so the V_{OC-triple} is between 1.9-Eₗₒₛₛ and 2*(1.1-Eₗₒₛₛ). The FFₜᵣᵢₚₗₑ of device 500 may be similar or the same as in device 200, while in one embodiment the J_{SC-triple} is J_{SC-visible}+12 mA/cm².

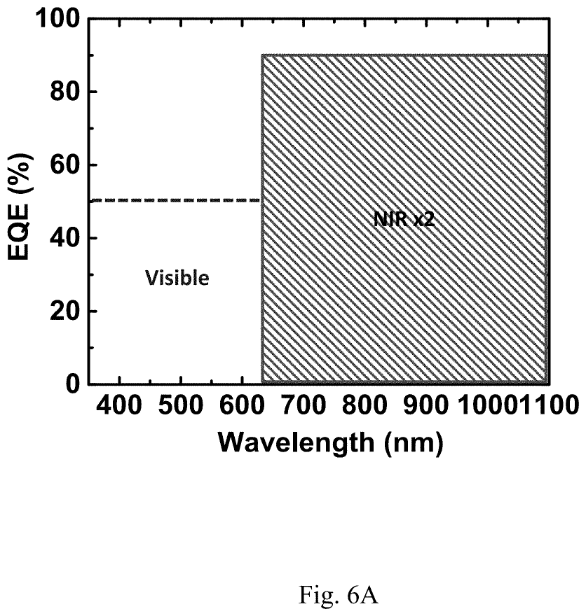

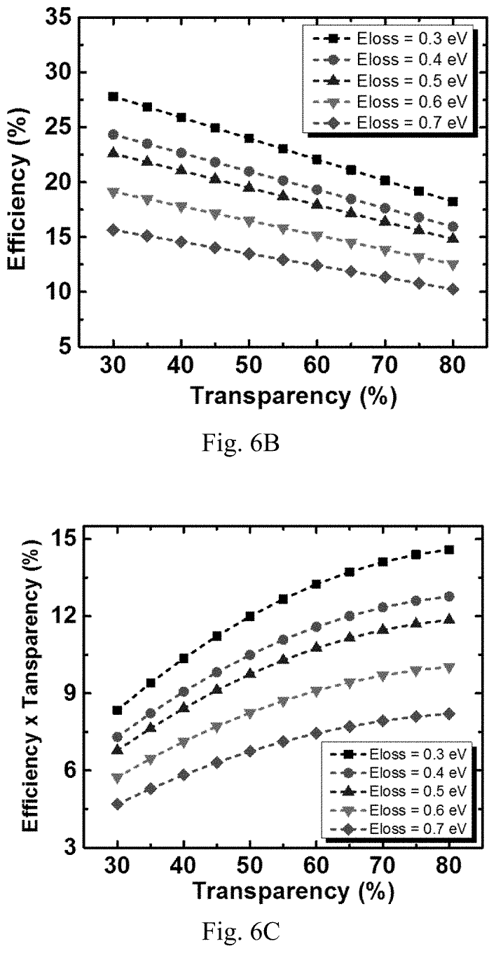

As shown in FIG. 5, the triple junction OPV consists of one visible subcell and two identical NIR subcells. As shown in FIG. 6A, the NIR subcells display EQE=90% over the absorption range of 640 nm to 1100 nm, with an energy gap of 1.1 eV. The visible subcell absorbing between 350 nm and 640 nm has an energy gap of 1.9 eV. With assumed energy loss, the sum of the V_{OC} of the two NIR subcells roughly equals that of the visible subcell. Therefore the two NIR subcells are connected in series, in parallel with the visible subcell to balance the voltage. In one embodiment, the two NIR subcells have a balanced photocurrent of 12 mA/cm², while the current density of the triple junction cell is the sum of the NIR pair and the visible subcell. In one embodiment, the balanced photocurrent of one or both of the NIR subcells is at least 6 mA/cm², at least 8 mA/cm², at least 10 mA/cm², at least 12 mA/cm², at least 14 mA/cm², at least 16 mA/cm², or at least 20 mA/cm².

The calculated efficiency as a function of transparency with different energy losses is plotted in FIG. 6B. As shown in FIG. 6B, decreasing transparency increases the current of the visible cell as well as the triple junction by the same amount. Compared with the previous case where the visible cell was the current limiting subcell, the slope of the efficiency depending on transparency is lower. The triple junction cell with 50% transparency at the visible and single junction energy loss of 0.5 eV shows 19.5% calculated efficiency. On the other hand, devices with higher transparency will not lose current as seriously as in the previous case due to the parallel configuration. The product of efficiency and transparency, therefore, monotonically increases with higher transparency (FIG. 6C).

In one embodiment, non-fullerene acceptors are paired with a donor with similar energy gap, and the energy level is fine-tuned to minimize energy loss, producing a triple junction cell with high transparency above 50% and an efficiency between 15% to 20%.

The disclosures of each and every patent, patent application, and publication cited herein are hereby incorporated herein by reference in their entirety. While devices and methods have been disclosed with reference to specific embodiments, it is apparent that other embodiments and variations of this disclosure may be devised by others skilled in the art without departing from the true spirit and scope of the disclosure. The appended claims are intended to be construed to include all such embodiments and equivalent variations.

1. An organic optoelectronic device, comprising:
a first electrode;
a first infrared photovoltaic subcell positioned over the first electrode;
a second infrared photovoltaic subcell positioned over the first near-infrared subcell;
a first visible photovoltaic subcell positioned over the second near-infrared subcell;
a second electrode positioned between the second near-infrared photovoltaic subcell and the first visible photovoltaic subcell; and
a third electrode positioned over the first visible photovoltaic subcell;
wherein the first electrode and the third electrode are held at the same potential relative to the second electrode.

2. The organic optoelectronic device of claim 1, wherein the first electrode and the third electrode are electrically connected.

3. The organic optoelectronic device of claim 1, wherein the first and second infrared photovoltaic subcells are near-infrared photovoltaic subcells having a response spectrum comprising a wavelength range of 640 nm to 1100 nm.

4. The organic optoelectronic device of claim 1, wherein the first infrared photovoltaic subcell has a response spectrum comprising a wavelength range of 800 nm to 1100 nm; and
wherein the second infrared photovoltaic subcell has a response spectrum comprising a wavelength range of 640 nm to 1100 nm.

5. The organic optoelectronic device of claim 1, wherein the first infrared photovoltaic subcell comprises a non-fullerene acceptor.

6. The organic optoelectronic device of claim 1, wherein the first visible photovoltaic subcell has a transparency from 30% to 80%.

7. The organic optoelectronic device of claim 6, wherein the first visible photovoltaic subcell has a transparency of about 50%.

8. The organic optoelectronic device of claim 1, wherein the sum of a V_{OC} of the first infrared photovoltaic subcell and a V_{OC} of the second infrared photovoltaic subcell is about equal to a V_{OC} of the first visible photovoltaic subcell.

9. The organic optoelectronic device of claim 1, wherein each of the first and second infrared photovoltaic subcells has a balanced photocurrent of at least 10 mA/cm².

10. The organic optoelectronic device of claim 9, wherein each of the first and second infrared photovoltaic subcells has a balanced photocurrent of at least 12 mA/cm².

11. The organic optoelectronic device of claim 1, further comprising a third infrared photovoltaic subcell positioned between the second infrared photovoltaic subcell and the second electrode.

12. An organic optoelectronic device, comprising:
a first electrode;
a first infrared photovoltaic subcell positioned over the first electrode;
a second infrared photovoltaic subcell positioned over the first near-infrared subcell;
a first visible photovoltaic subcell positioned over the second near-infrared subcell; and
a second electrode positioned over the first visible photovoltaic subcell;
wherein the first electrode and the third electrode are held at the same potential relative to the second electrode.

13. The organic optoelectronic device of claim 12, further comprising a third electrode positioned between the second infrared photovoltaic subcell and the first visible photovoltaic subcell.

14. The organic optoelectronic device of claim 12, wherein the first infrared photovoltaic subcell has a response spectrum comprising a wavelength range of 800 nm to 1100 nm; and
wherein the second infrared photovoltaic subcell has a response spectrum comprising a wavelength range of 640 nm to 840 nm.

15. The organic optoelectronic device of claim 12, wherein the first visible photovoltaic subcell has a response spectrum comprising a wavelength range of 350 nm to 640 nm.

16. The organic optoelectronic device of claim 12, wherein the first infrared photovoltaic subcell comprises a non-fullerene acceptor.

17. The organic optoelectronic device of claim 12, wherein the first visible photovoltaic subcell has a transparency from 30% to 80%.

18. The organic optoelectronic device of claim 12, wherein the energy loss of each subcell is in a range from 0.3 to 0.7 eV.

19. The organic optoelectronic device of claim 12, wherein a V_{OC} from the first electrode to the second electrode is at least 2.4 V.

20. The organic optoelectronic device of claim 19, wherein the V_{OC} from the first electrode to the second electrode is at least 3 V.
